(19) United States
(12) Patent Application Publication
(10) Pub. No.: US 2009/0190388 A1
(43) Pub. Date: Jul. 30, 2009

(54) RESISTIVE MEMORY AND METHODS FOR FORMING SAME

(76) Inventors: Rainer Bruchhaus, Sunnyvale, CA (US); Ulrike Gruening Von Schwerin, Munich (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 12/019,364

(22) Filed: Jan. 24, 2008

(51) Int. Cl. G11C 11/00; H01L 21/20

(52) U.S. Cl. 365/148; 438/382; 257/E21.004

(57) ABSTRACT

A method of fabricating a resistive storage device is provided. The method generally comprises providing an electrode structure stack comprising a first electrode and an electrode structure mask arranged at the first electrode, forming a support structure at least partly at the electrode structure mask, removing the electrode structure mask to leave a storage region window in the support structure, and forming a resistive storage region in the storage region window at the first electrode.

### BACKGROUND OF THE INVENTION

Resistive storage devices and integrated circuits comprising resistive storage regions or resistive storage cells are becoming increasingly more important in the field of micro electronics, particularly for nonvolatile storage applications, for example.

### BRIEF DESCRIPTION OF THE DRAWINGS

Details of one or more implementations are set forth in the accompanying drawings and description below. Other features will be apparent from the description and drawings, and from the claims.

FIGS. 1A to 1C show schematic cross sections of integrated circuits according to one embodiment;

FIG. 2A shows a schematic top view of an integrated circuit according to another embodiment;

FIGS. 2B to 2D show schematic cross sections of the integrated circuit of FIG. 2A along the section planes A-A, B-B, and C-C, respectively according to one embodiment;

FIGS. 3A to 3N show schematic cross sections of an integrated circuit at different stages during another method of fabricating the integrated circuit according to yet another embodiment;

FIGS. 3A′ to 3N′ show schematic top views of the integrated circuit in accordance with FIGS. 3A to 3N; and

FIG. 4 shows a system according to one embodiment.

### DETAILED DESCRIPTION OF THE PREFERRED EMBODIMENT

Embodiments of the invention relate to self-alignment in storage devices, in particular resistive storage devices and integrated circuits comprising resistive storage regions or resistive storage cells.

In one embodiment, an integrated circuit comprises a substrate having a substrate normal direction and a first structured electrical connection layer. In this embodiment, the first structured electrical connection layer comprises a first electrode and a first electrical interconnection line. The integrated circuit further comprises a resistive storage region arranged, in substrate normal direction, on top of the first electrode; and an interconnection structure mask arranged, in substrate normal direction, on top of the first electrical interconnection line.

In one embodiment, the first electrical interconnection line may be separated from the first electrode by a dielectric filling structure that comprises material different from material of the interconnection structure mask. In particular, the interconnection structure mask may be formed as lithographic hard mask comprising dielectric material that differs from the dielectric material comprised in the dielectric filling structure.

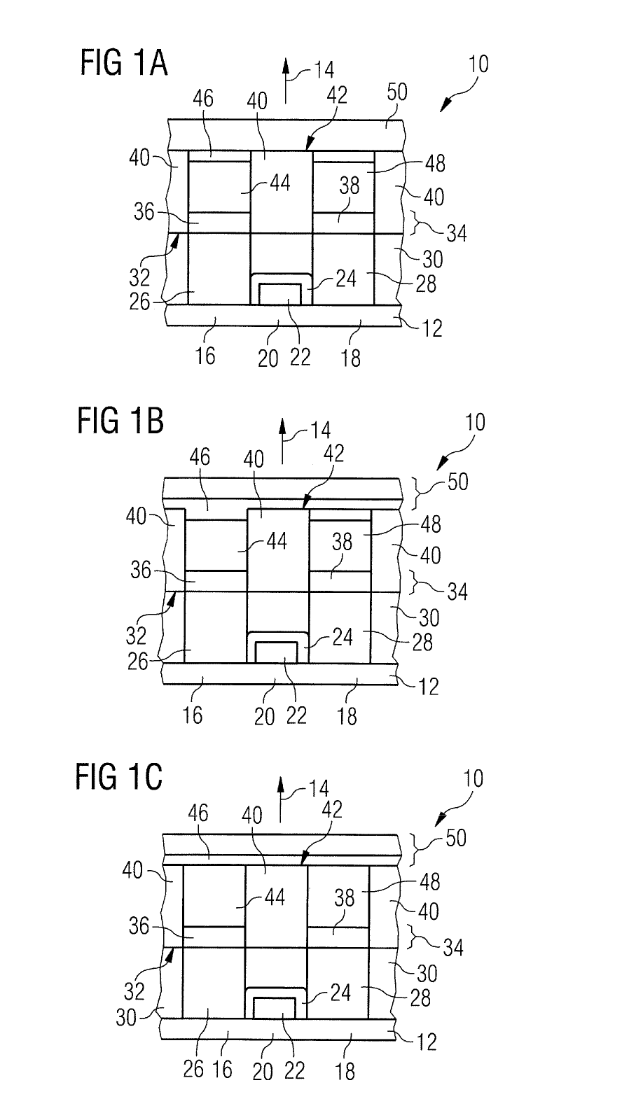

FIG. 1A shows a schematic cross section of a first integrated circuit 10. According to an embodiment, the integrated circuit 10 may comprise or form a resistive storage device. In particular, the integrated circuit may comprise at least one resistive storage cell. As shown in FIG. 1A, a substrate 12 having a substrate normal direction 14 may be provided with a first source/drain region 16 and a second source/drain region 18 of a select transistor. A channel region 20 of the select transistor may be controlled by a gate electrode 22 that is at least partly covered by a gate cover isolation 24. The first and second source/drain regions 16, 18 may be electrically connected with an electrically conductive first via conductor 26 and an electrically conductive second via conductor 28, respectively. The first and second via conductors 26, 28 are embedded in a pre-metal dielectric layer 30 (PMD). Accordingly, in this embodiment a select circuit structure is provided with a substantially planar surface, such as a substantially planar process surface 32.

As shown in the integrated circuit 10 of FIG. 1A, a first structured electrical connection layer 34 may be arranged at the process surface 32. In particular, the first structured electrical connection layer 34 may be laterally structured to comprise at least one first electrode 36 and at least one first electrical interconnection line 38. As shown in FIG. 1A the first electrical interconnection line 38 may be laterally separated from the first electrode 36. Moreover, a dielectric filling structure 40 may be at least partly arranged between the first electrode 36 and the first electrical interconnection line 38. In one embodiment, the dielectric filling structure 40 may comprise dielectric material, such as SiO₂, for example. In another embodiment, the dielectric filling structure 40 may comprise substantially the same material as the pre-metal dielectric layer 30. Nevertheless, the integrated circuit 10 is not limited to this condition. In another embodiment, the dielectric filling structure 40 may comprise dielectric material different from the pre-metal dielectric layer 30.

In the example of FIG. 1A, opposite to the process surface or process interface 32, the dielectric filling structure 40 may form at least part of an interconnection interface 42. In one embodiment, the interconnection interface 42 may be substantially planar and parallel to the process surface 32. The process surface 32 and/or the interconnection interface 42 may be substantially perpendicular to the substrate normal direction 14. The thickness of the dielectric filling structure 40, in substrate normal direction, may be between about 30 nm and about 100 nm, or between about 40 nm and about 80 nm, for example. Nevertheless, the integrated circuit 10 is not limited to this thickness of the dielectric filling structure 40. In another embodiment, the thickness of the dielectric filling structure 40, in substrate normal direction, may be equal to greater than about 100 nm. In yet another embodiment, the thickness of the dielectric filling structure 40, in substrate normal direction, may be equal to or smaller than about 30 nm.

According to the embodiment of FIG. 1A, the integrated circuit further comprises a resistive storage region 44 that may be arranged, in substrate normal direction, on top of the first electrode 36. The lateral position and/or size of the resistive storage region 44, i.e. the position and/or extension of the resistive storage region 44 in the directions perpendicular to the substrate normal direction, may be substantially identical to that of the first electrode 36. Accordingly, the resistive storage region 44 is precisely aligned with the first electrode 36 in lateral directions. This may be achieved by self-alignment as described below, for example.

In one embodiment, the resistive storage region 44 may comprise material that may exhibit at least two different states of electrical conductance or electrical resistance. This may be achieved by forming conductive paths, filaments or bridges within the material or by a phase change in the material. Accordingly, in one embodiment the integrated circuit 10 may be a conductive bridging RAM (CBRAM). In this embodiment, the resistive storage region 44 may comprise a solid state electrolyte, such as a chalcogenide, for example. In another embodiment, the integrated circuit 10 may be a phase change RAM (PCRAM). Nevertheless, the integrated circuit 10 is not limited to one of these devices. Also devices that combine both of these memory concepts or other resistive memory cells may be realized by or comprised in the integrated circuit 10. In another embodiment, the integrated circuit 10 may be a switchable resistive storage device, where the resistive storage region 44 comprises a transition metal oxide, such as nickel oxide, for example. In another embodiment, the resistive storage region 44 may comprise TiO₂, Fe₂O₃, CoO, Cr-doped SrTiO₃, or combination thereof, though the resistive storage region 44 is not limited to these materials.

Moreover, in the embodiment of FIG. 1A, a second electrode 46 may be arranged, in substrate normal direction, on top of the resistive storage region 44. The lateral position and/or size of the second electrode 46, i.e. the position and/or extension of the second electrode 46 in the directions perpendicular to the substrate normal direction, may be substantially identical to that of the first electrode 36 and/or the resistive storage region 44. Accordingly, at least part of the second electrode 46 may be precisely aligned with the resistive storage region 44 in lateral directions. This may be achieved by self-alignment as described below, for example. The second electrode 46 may comprise metal material, such as Pt, Ir, iridium oxide, ruthenium oxide, for example.

In another embodiment of the integrated circuit 10, an interconnection structure mask 48 is arranged, in substrate normal direction 14, on top of the first electrical interconnection line 38. The lateral position and/or size of the interconnection structure mask 48, i.e. the position and/or extension of the interconnection structure mask 48 in the directions perpendicular to the substrate normal direction, may be substantially identical to that of the first electrical interconnection line 38. Accordingly, the interconnection structure mask 48 is precisely aligned with the first electrical interconnection line 38 in lateral directions. In one embodiment, this may be achieved by self-alignment as described below. In the embodiment shown in FIG. 1A, the interconnection structure mask 48 may comprise material that is different from the material of the dielectric filling structure 40 which, in turn, may form together with the interconnection structure mask 48 at least part of the substantially planar interconnection interface 42. In particular, the interconnection structure mask 48 may comprise a hard mask material, such as Si₃N₄, for example.

The integrated circuit 10 according to the example of FIG. 1A further comprises a second electrical interconnection line 50 that may be arranged at the interconnection interface 42 and electrically connected to the resistive storage region 44 via the second electrode 46. The second electrical interconnection line 50 may be at least partly arranged at the interconnection structure mask 48 which separates the second electrical interconnection line 50 from the first electrical interconnection line 38. Accordingly, the interconnection structure mask 48 may provide an electrical insulation of the second electrical interconnection line 50 from the first electrical interconnection line 38. In one embodiment, the second electrical interconnection line 50 may form a bit line of the resistive memory device. The second electrical interconnection line 50 may comprise metal material, such as Al or Cu, for example.

In the embodiment of FIG. 1A the second electrode 46 comprises a surface that forms at least part of the substantially planar interconnection interface 42. In this embodiment, the resistive storage region 44 is recessed with respect to the interconnection interface 42 such that the second electrode 46 is totally arranged in the resulting recess. In another example shown in FIG. 1B, the second electrode 46 is comprised in the second electrical interconnection line 50 and may be at least partly arranged at the interconnection interface 42.

The embodiments shown in FIGS. 1B and 1C are similar to the embodiment of FIG. 1A. Accordingly, corresponding elements and features are designated with the same reference numerals, and for a more detailed description it is referred to the respective description of the integrated circuit 10 of FIG. 1A.

Although the detailed structure and arrangement of the second electrode 46 and the respective contacting of the resistive storage region 44 differs in the examples of FIGS. 1A to 1C, in all of these examples the integrated circuit comprises a second structured electrical connection layer arranged at the interconnection interface 42, wherein the second structured electrical connection layer comprises the at least one second electrical interconnection line 50 that is electrically connected to the resistive storage region 44.

According to the embodiments shown in FIGS. 1A to 1C, the first electrode 36 may be electrically connected to the first source/drain region 16 through the first via conductor 26, and the first electrical interconnection line 38 may be electrically contacted to the second source/drain region 18 of the select transistor through the second via conductor 28. The first electrical interconnection line, therefore, may form a ground line or a plate line of a resistive memory device, for example.

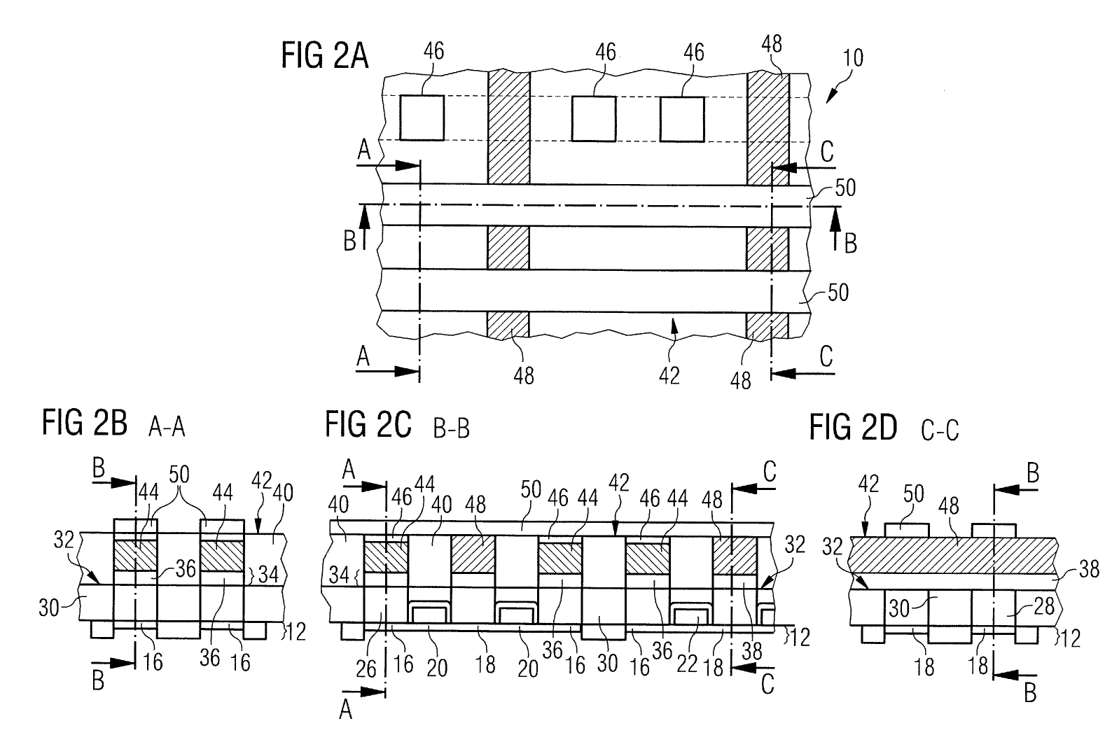

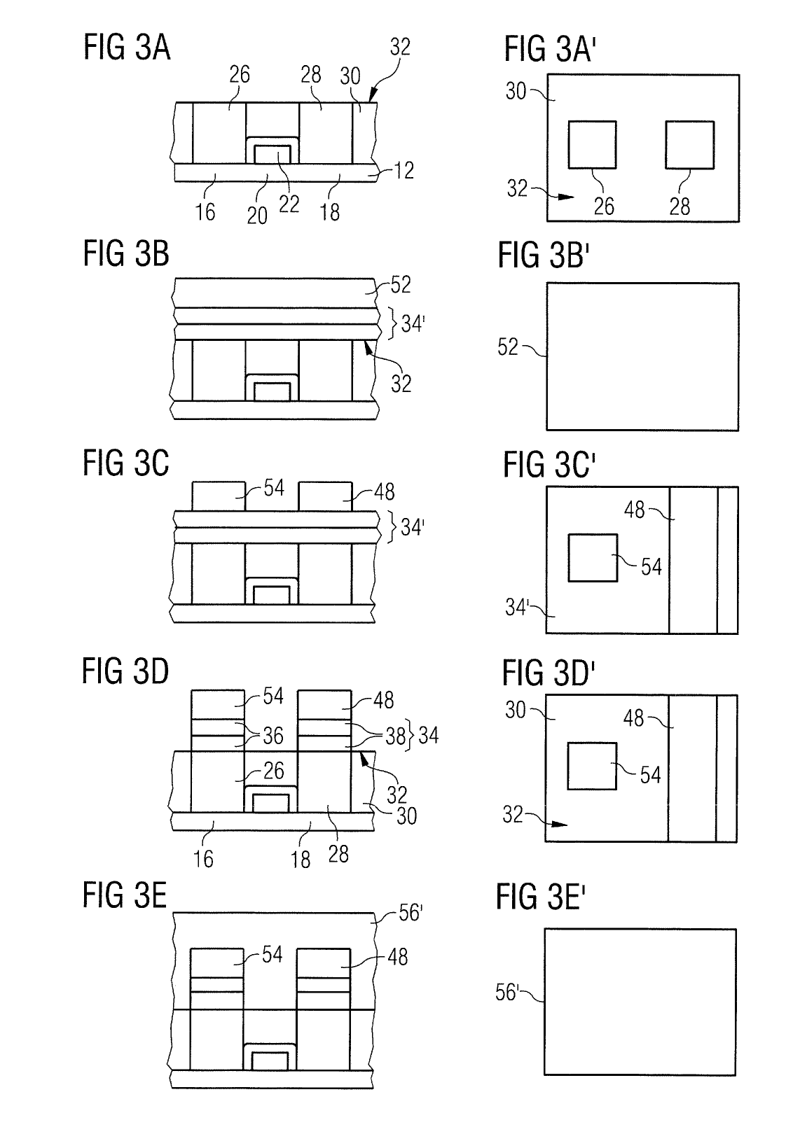

FIGS. 2A to 2D show an integrated circuit 10 according to another embodiment, where FIG. 2A represents a schematic top view onto an interconnection interface 42 with a plurality of second electrical interconnection lines 50 arranged at the interconnection interface 42. Accordingly, the substrate normal direction of the integrated circuit shown in FIG. 2A is perpendicular to the drawing plane of FIG. 2A. FIGS. 2B to 2D illustrate schematic cross sections of the integrated circuit of FIG. 2A along the sectional planes A-A, B-B, and C-C, respectively.

According to this embodiment, the integrated circuit may form a resistive storage device 10, that comprises a substrate 12 having a substrate normal direction 14; a first structured electrical connection layer 34, comprising a plurality of first electrodes 36 that are arranged in an array comprising rows and columns; and a first electrical interconnection line 38. In particular, in the example shown in FIGS. 2A to 2D, the integrated circuit 10 comprises a plurality of first electrical interconnection lines 38. Moreover, the integrated circuit 10 may further comprise a plurality of resistive storage regions 44 each being arranged, in substrate normal direction 14, on top of one of the plurality of first electrodes 36. An interconnection structure mask 48 may be arranged, in substrate normal direction 14, on top of the first electrical interconnection line 38.

A shown in FIGS. 2A, 2B and 2D, a plurality of second electrical interconnection lines 50 may be at least partly separated from the first electrical interconnection line 38 through the interconnection structure mask 48, wherein the resistive storage regions 44 within each column may be electrically connected to a common second electrical interconnection line 50, as shown in FIG. 2C, for example. This is also illustrated in the upper portion of FIG. 2A, where one of the second electrical interconnection lines 50 is shown as a dotted contour to make the underlying second electrodes 46 visibly through which the resistive storage regions 44 are electrically connected to the respective second electrical interconnection line 50.

In the embodiment of FIGS. 2A to 2D, the integrated circuit 10 may comprise a plurality of select transistors that are arranged in an array comprising rows and columns. In particular, each select transistor may be assigned to one resistive storage region 44, wherein the gate electrodes 22 of select transistors within one row are formed by a common word line. As particularly shown in FIG. 2C, two adjacent select transistors may share one common second source/drain region 18, which is electrically connected to the one of the first electrical interconnection lines 38 through one of the second via conductors 28. The first electrical interconnection lines 38 may extend in a longitudinal direction substantially parallel to the word lines. Accordingly, the second source/drain regions 18 of the select transistor within the same row may be electrically connected to a common first electrical interconnection line 38. The first electrical interconnection lines 38, therefore, may form ground lines or plate lines of the resistive storage device formed by the integrated circuit 10. The second electrical interconnection lines 50, on the other hand, may extend in a longitudinal direction, substantially perpendicular to the word lines and the first electrical interconnection lines 38, and may form bit lines of the resistive storage device.

In one embodiment, the width of the first electrodes 36, in directions perpendicular to the substrate normal direction, is between about 10 nm and about 100 nm, or between about 30 nm and about 80 nm, for example. Nevertheless, the integrated circuit 10 is not limited to this width of the first electrodes 36. In another embodiment, the width of one or more of the first electrodes 36, in directions perpendicular to the substrate normal direction, may be equal to greater than about 100 nm. In yet another embodiment, the width of one or more of the first electrodes 36, in directions perpendicular to the substrate normal direction, may be equal to or smaller than about 10 nm.

In another embodiment, a method of fabricating an integrated circuit, such as one of the above described integrated circuits 10, for example, comprises providing an electrode structure stack comprising a first electrode, such as one of the above described first electrodes 36, for example, and an electrode structure mask arranged at the first electrode. A support structure, such as one of the above described dielectric filling structure 40, for example, at least partly at the electrode structure mask. The electrode structure mask may be removed to leave a storage region window in the support structure, and a resistive storage region, such as one of the above described resistive storage regions 44 may be arranged in the storage region window at the first electrode.

Accordingly, the electrode structure mask that may be comprised in the electrode structure stack at least partly defines the position of the storage region window. Therefore, the method enables a self-aligned arrangement of the resistive storage region at the first electrode. This first electrode may be formed as a bottom contact or bottom electrode of a resistive storage cell, for example. According to one aspect a method of fabricating an integrated circuit may comprise structuring a first electrical connection layer to provide at least one bottom contact; and self-aligned arrangement of a storage region at the bottom contact.

The electrode structure stack may be formed as a stacked layer sequence comprising a layer formed by the first electrode and another layer formed by the electrode structure mask. In one embodiment, this layer sequence may define a layer normal direction such that the layer formed by the first electrode and/or the layer formed by the electrode structure mask extend laterally in directions substantially perpendicular to the layer normal direction. Accordingly, the first electrode and the electrode structure mask may be arranged on top of each other in the layer normal direction, i.e. they may be stacked in the layer normal direction. This layer normal direction may coincide with a substrate normal direction, such as the substrate normal direction 14 described above.

In another embodiment, a method of fabricating an integrated circuit, such as one of the above describe integrated circuits 10, for example, comprises forming an interconnection structure mask, such as one of the above described interconnection structure masks 48, for example, at a first electrical connection layer. Similar to above described examples, the interconnection structure mask may comprise dielectric material, while the electrical connection layer comprises electrically conductive material, in one example. The method may, for example, comprise etching at least part of the first electrical connection layer with the interconnection structure mask being applied as an etch mask to form at least one first electrical interconnection line, such as one of the above described first electrical interconnection lines, for example.

According to this embodiment, the method may further comprise depositing a dielectric layer that may, for example, comprise dielectric filling material in accordance with the material of one of the support structures or dielectric filling structures described herein. Furthermore, the method may comprise planarizing the dielectric layer to at least partly uncover the interconnection structure mask, and forming at least one second electrical interconnection line, such as one of the above described second electrical interconnection lines, for example, at least partly at the uncovered interconnection structure mask.

Accordingly, the interconnection structure mask may be applied as an etch mask for forming the at least one first electrical interconnection line from the first electrical connection layer. The interconnection structure mask, however, is not removed after the etch process. Therefore, in this embodiment it may be refrained from a step of removing the interconnection structure mask, resulting in a simple and efficient fabrication process.

In yet another embodiment, a method of fabricating an integrated circuit, such as one of the above described integrated circuits, for example, comprises forming a structure mask at a first electrical connection layer, the structure mask comprising an electrode structure mask and an interconnection structure mask, such as one of the above described interconnection structure masks 48, for example. The method may further comprise etching at least part of the first electrical connection layer with the structure mask being applied as an etch mask to form at least one first electrode, such as one of the above describe first electrodes 36, for example, and at least one first electrical interconnection line, such as one of the above described first electrical interconnection lines 38, for example.

According to this embodiment, the method may further comprise depositing a dielectric filling material and planarizing the dielectric filling material to at least partly uncover the electrode structure mask. According to one example, a support structure, such as a dielectric filling material as described above, may be provided. Moreover, the method may comprise removing the electrode structure mask to uncover at least part of the first electrode, while maintaining the interconnection structure mask and forming a resistive storage region, such as one of the above described resistive storage regions 44, for example, at the first electrode.

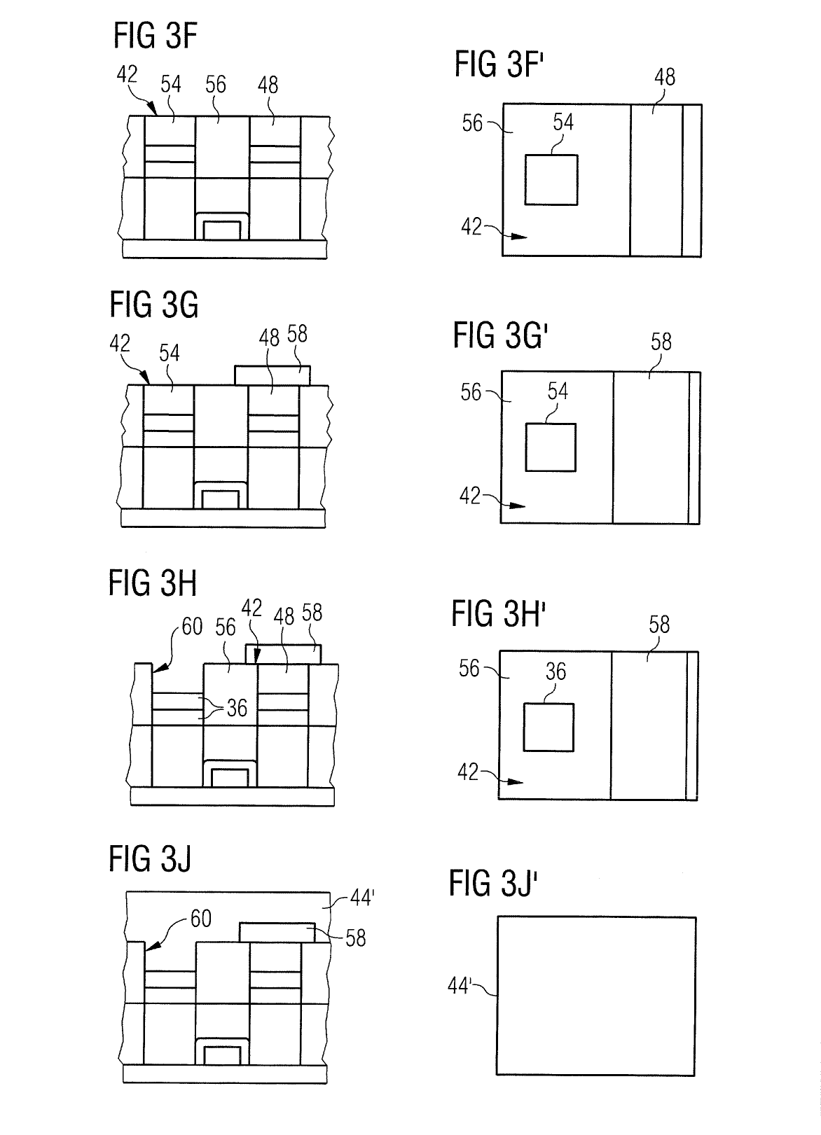

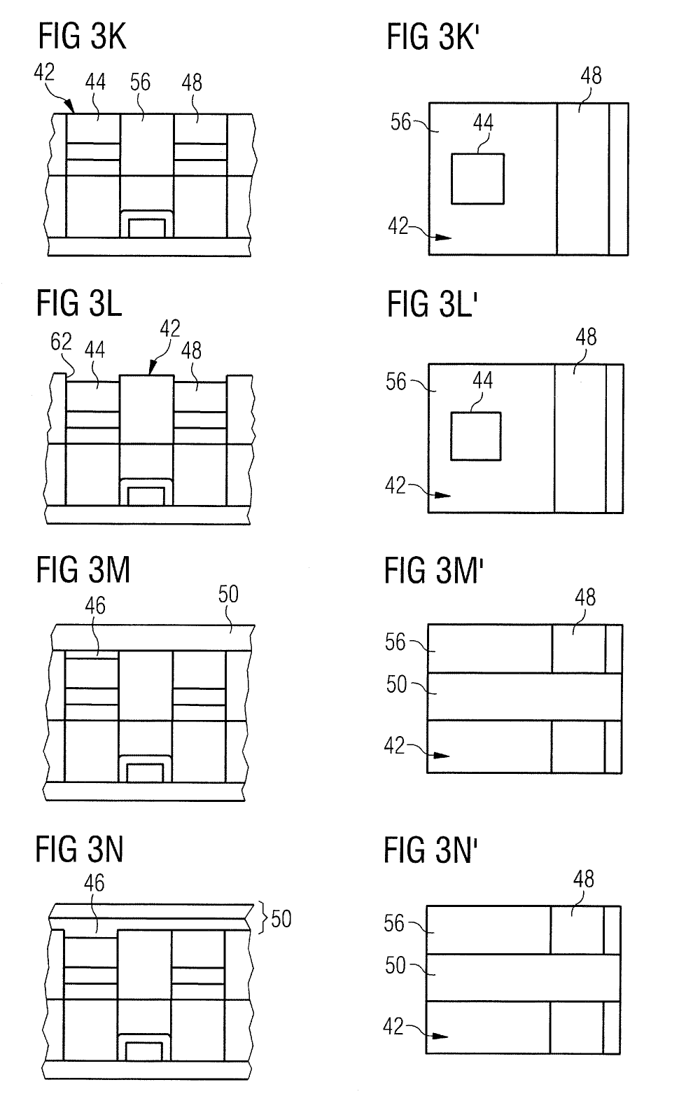

FIGS. 3A to 3N and 3A′ to 3N′ schematically illustrate a method of fabricating an integrated circuit. FIGS. 3A to 3N show schematic cross sections of an integrated circuit at different stages during a method of fabricating the integrated circuit, while FIGS. 3A′ to 3N′ illustrate top views of the circuit at the stages illustrated in FIGS. 3A to 3N, where a substrate normal direction may be perpendicular to the drawing plane of FIGS. 3A′ to 3N′.

According to this embodiment, the integrated circuit may comprise or form a resistive storage device. In particular, the integrated circuit may comprise at least one resistive storage cell. As shown in FIG. 3A, a select circuit comprising a select transistor may be provided with a substantially planar process surface 32 similar to one of the above described integrated circuits 10, for example.

As shown in FIG. 3B, in one method a first electrical connection layer 34′ is formed or arranged at the process surface 32. The first electrical connection layer 34′ may consist of a single electrically conductive layer. In another embodiment, as shown in FIG. 3B, the first electrical connection layer 34′ comprises a sequence of two layers, where the first layer arranged at the process surface 32 may comprise tungsten (W) and the second layer deposited on the tungsten layer may comprise platinum (Pt), for example. In yet another embodiment, an additional layer of titanium (Ti) may be arranged between the W layer and the Pt layer, for example. In one particular example, the first electrical connection layer 34′ may be deposited by sputtering. Nevertheless, the first electrical connection layer is not limited to these materials. Depending the particular requirements for the application of the integrated circuit, for example, other electrically conductive materials may be applied.

In the embodiment shown in FIG. 3B, the method further comprises forming a structure mask layer 52 at the first electrical connection layer 34′. This structure mask layer 52 may be lithographically structured to form an electrode structure mask 54, as shown in FIG. 3C, for example. Accordingly, the electrode structure mask 54 may form a part of the structure mask layer 52. In one embodiment, the structure mask layer 52 may form a lithographic hard mask that is deposited at the first electrical connection layer 34′. In particular, the structure mask layer 52 may comprise silicon nitride, such as Si₃N₄, for example. The structure mask layer 52 may be provided with a thickness of between about 30 nm and about 100 nm, or between about 40 nm and about 80 nm, for example. Nevertheless, the structure mask layer 52 is not limited to this thickness but may be provided with a thickness of even more than 100 nm or less than 30 nm, in other examples.

In another embodiment, also demonstrated in the shown example of a method, the structure mask layer 52 may be lithographically structured to form an interconnection structure mask 48, as shown in FIG. 3C. Accordingly, the interconnection structure mask 48 may form a part of the structure mask layer 52. In one example, the electrode structure mask 54 and the interconnection structure mask 48 may be formed simultaneously by lithographically structuring the structure mask layer 52. The structure mask that is formed or arranged at the first electrical connection layer 34′, therefore, comprises the electrode structure mask 54 and the interconnection structure mask 48. Accordingly, in this aspect of a method, forming the structure mask at the first electrical connection layer 34′ comprises forming the structure mask layer 52 at the first electrical connection layer 34′, and lithographically structuring the structure mask layer 52 to simultaneously form the electrode structure mask 54 and the interconnection structure mask 48.

In a further embodiment, the method comprises etching at least part of the first electrical connection layer 34′, while applying the electrode structure mask 54 as an etch mask, as shown in FIG. 3D, resulting in a structured electrical connection layer 34. In particular, the electrode structure mask 54 is arranged at the first electrical connection layer 34′ such that it partly or locally covers or protects the first electrical connection layer 34′. The first electrical connection layer 34′ may be structured to form the first electrode 36 by at least partly removing the first electrical connection layer 34′ at regions or areas where it is not covered or protected by the electrode structure mask 54.

Accordingly, the method results in the formation of the first electrode 36 as a portion of the first electrical connection layer 34′ that is covered or protected by the electrode structure mask 54. This may enable a precise and simple fabrication of an electrode structure stack formed by the first electrode 36 and the electrode structure mask 54. In particular, the position and/or shape of the first electrode 36 is easily adapted to the position and/or shape of the electrode structure mask 54.

In another embodiment, the method may comprise etching at least part of the electrical connection layer 34′ with the interconnection structure mask being applied as an etch mask to form at least one first electrical interconnection line 38, as shown in FIG. 3D, for example. In one embodiment, the first electrode 36 and the first electrical interconnection line 38 may be structured simultaneously by etching. In the process of etching at least part of the first electrical connection layer 34′, the position and/or shape of the at least one first electrode 36 may be defined by the electrode structure mask 54, while the position and/or shape of the at least one first electrical interconnection line 38 may be defined by the interconnection structure mask 48.

As shown in the example of FIG. 3D, the first electrode 36 may be electrically connected with a first source/drain contact 16 of a select transistor through a via conductor 26, while the first interconnection line 38 may be electrically connected with a second source/drain contact 18 of the select transistor.

In another embodiment, not explicitly shown in the figures, providing the electrode structure stack may comprise forming the structure mask layer 52 at the first electrical connection layer 34′ and simultaneously or sequentially etching the structure mask layer and the first electrical connection layer with a stack structure mask being applied as an etch mask for the formation of the electrode structure stack. The stack structure mask may be arranged at the structure mask layer 52 and may be structured lithographically and removed after etching, for example. With this method a precise and easy adjustment of the positions and/or shapes of the first electrode 36 and the electrode structure mask 54 may be achieved.

As shown in FIG. 3E and FIG. 3F according to one embodiment, a support structure 56 may be arranged at least partly at the electrode structure mask 54. In one embodiment, forming the support structure 56 may comprise depositing a support material layer 56′ (FIG. 3E) and planarizing the support material layer 56′ to at least partly uncover the electrode structure mask 54 (FIG. 3F). The planarized support material layer 56′, therefore, forms the support structure 56.

Depositing the support material layer 56′ may comprise depositing a substantially continuous layer of support material, such as dielectric material. This substantially continuous layer may cover large parts of the device, including the electrode structure stack, i.e. the first electrode 36 and the electrode structure mask 54. A surface of the support material layer 56′ after deposition may be uneven due to the underlying surface structure formed by the locally arranged electrode structure stack. Planarizing the support material may comprise chemical-mechanical polishing (CMP). The support material layer 56′ may be chemically-mechanically polished at least until a portion of the electrode structure mask 54 is uncovered. In one example, planarization may be stopped as soon as at least part of the electrode structure mask 54 is uncovered. The polishing process may be effectively stopped through applying a material for the electrode structure mask 54 that has a higher chemical-mechanical resistance or stability for the applied CMP process than the material applied for the support material layer 56′ or the support structure 56.

In one another embodiment, the support material layer 56′ may comprise dielectric material, such as SiO₂, for example. Accordingly, forming the support structure 56 may comprise depositing a dielectric layer, such as a SiO₂ layer, for example, and planarizing the dielectric layer to at least partly uncover the electrode structure mask 54. Accordingly, the support structure may form a dielectric filling structure, such as one of the above describe dielectric filling structures 40 or a support structure 56, for example. This is also demonstrated in FIGS. 3E and 3F when the support material layer 56′ is identified as the dielectric layer 56′.

According to another embodiment also shown in FIGS. 3E and 3F, the interconnection structure mask 48 may be at least partly covered with the dielectric layer 56′. After deposition of the dielectric layer 56′, the surface thereof may be uneven due to the underlying surface structure formed by the locally arranged interconnection structure mask 48 and the at least one first interconnection line 38, for example. Moreover, also other underlying surface structures or interface structures, such as an electrode structure stack as described above, for example, may contribute to a certain roughness of the surface of the dielectric layer 56′.

According to this embodiment, planarizing the dielectric layer 56′ may comprise chemical-mechanical polishing (CMP). The dielectric layer 56′ may be chemically-mechanically polished at least until a portion of the interconnection structure mask 48 is uncovered. In one embodiment, planarization may be stopped as soon as at least part of the interconnection structure mask 48 is uncovered. The polishing process may be effectively stopped through applying a material for the interconnection structure mask 48 that has a higher chemical-mechanical resistance or stability for the applied CMP process than the material applied for the dielectric layer 56′. In this example, the thickness of the interconnection structure mask 48 may define a reliable and predictable stop position for polishing. Therefore, in this embodiment the method may provide a reliable and highly reproducible fabrication of an integrated circuit 10. The planarized dielectric layer 56′ may form a dielectric filling structure, such as one of the above described dielectric filling structures 40 or the support structure 56, for example.

In one embodiment, the support material layer or dielectric layer 56′ may be deposited with a thickness in layer normal direction and/or the substrate normal direction 14 that is not smaller than the thickness of the electrode structure stack and/or the thickness of the first electrical interconnection line 38 and the interconnection structure mask 48 together, in the layer normal direction and/or the substrate normal direction 14. In this embodiment, a substantially planar surface can be easily achieved through planarizing the support material layer or dielectric layer 56′, even when planarizing is stopped as soon as the electrode structure mask 54 and/or the interconnection structure mask 48 is at least partly uncovered. In particular, a planarized surface of the support structure 56 or dielectric filling structure and an uncovered surface of the electrode structure mask 54 and/or the interconnection structure mask 48 may substantially lie in a common plane and form a substantially continuous surface, such as the interconnection interface 42 described above, for example.

As shown in FIG. 3G, a protection mask 58 may be provided that covers the uncovered interconnection structure mask 48. In particular, the protection mask 58 may be arranged at the uncovered interconnection structure mask 48 before the electrode structure mask 54 is removed. In this embodiment, the protection mask 58 may protect the interconnection structure mask 48 from being removed, damaged or corroded during a removal of the electrode structure mask 54.

FIG. 3H demonstrates a removal of the electrode structure mask 54, according to one embodiment of fabricating an integrated circuit. Particularly, removing the electrode structure mask 54 may comprise etching the electrode structure mask 54 selective to the support structure 56 and the first electrode 36. Selectively etching may comprise chemically etching the material of the electrode structure mask 54 with a chemical selectivity to the material of the support structure 56, such as the dielectric material, for example, and to the material of the first electrode 36. Accordingly, in this embodiment, the support structure 56 and the first electrode 36 comprise material different from the material of the electrode structure mask 54. During etching the electrode structure mask 54, the interconnection structure mask 48 may be protected by the protection mask 58 so that the interconnection structure mask 48 is not etched even if it comprises the same material as the electrode structure mask 54.

After removal of the electrode structure mask 54 a cavity may remain that forms a storage region window 60 as shown in FIG. 3H. This cavity may extend from the substantially planar surface, such as the interconnection interface 42, of the support structure 56 to the first electrode 36. In particular, a surface of the first electrode 36 is uncovered through removing the electrode structure mask 54.

As shown in FIG. 3J and FIG. 3K, a resistive storage region 44 may be arranged in the storage region window 60 at the first electrode 36. According to one embodiment, forming the resistive storage region 44 comprises depositing a storage medium layer 44′ at least partly in the storage region window 60 and planarizing the storage medium layer 44′ to at least partly uncover the support structure 56. In particular, in this embodiment the method may comprise at least partly removing the storage medium layer 44′ outside the storage region window 60 by chemical-mechanical polishing (CMP). Accordingly, the portion of the storage medium layer 44′ remaining inside the storage region window 60 after chemical-mechanical polishing may form the resistive storage region 44. A substantially planar surface, such as the interconnection interface 42 may be provided or uncovered by this CMP process.

The storage medium layer 44′, particularly the resistive storage medium 44, may comprise material that may exhibit at least two different states of electrical conductance or electrical resistance. This may be achieved by forming conductive bridges within the material or by a phase change in the material. The resistive storage region 44 may, for example, comprise a transition metal oxide, a solid state electrolyte, or a phase change material. Accordingly, in one embodiment the integrated circuit 10 may be a CBRAM. In another embodiment the integrated circuit 10 may be a PCRAM. Nevertheless, the method is not limited to one of these devices. Also devices that combine more than one of these memory concepts or other resistive memory cells may be fabricated according to this method. In another embodiment, the resistive storage region 44 comprises nickel oxide, such as NiO. In another example, the resistive storage region 44 may comprise TiO₂, Fe₂O₃, CoO, Cr-doped SrTiO₃, or combination thereof, though the resistive storage region 44 is not limited to these materials.

Accordingly, the electrode structure mask 54 may be applied both for structuring the first electrode 36 and the resistive storage region 44 formed by a resistive storage medium. Firstly, the electrode structure mask 54 defines the position and/or shape of the first electrode 36, when applied as the etch mask for the formation of the first electrode 36 through etching, as shown in FIG. 3D, for example. Secondly, the electrode structure mask 54 defines the position and/or shape of the storage region window 60 and, thus, the position and/or shape of the resistive storage region 44. Therefore, the method results in a self-aligned arrangement of the resistive storage region 44 at the first electrode 36.

FIG. 3L shows another process of providing a recess 62 in the planarized surface at the resistive storage region 44. This recess may be provided by selectively etching part of the resistive storage region 44. Moreover, as shown in FIG. 3M, a second electrode 46 may be arranged at the resistive storage region 44, particularly in the recess 62. This may be achieved by depositing an electrode layer and subsequently planarizing the electrode layer such that only the portion of the deposited electrode layer inside the recess 62 remains as the second electrode 46.

According to another example shown in FIG. 3N, an electrode layer may be deposited that forms the second electrode 46 without planarizing the electrode layer. Accordingly, in this embodiment the second electrode 46 extends also outside the recess 62. In yet another embodiment that may result in an integrated circuit shown in FIG. 1C, for example, no recess 62 may be formed and an electrode layer is deposited to directly form the second electrode 46 at a substantially planar surface, for example. The second electrode 46 may comprise electrically conductive material that provides electrical connection to the resistive storage region 44. In particular, the second electrode 46 may comprise platinum (Pt), iridium oxide, or ruthenium oxide, for example.

As shown in FIGS. 3M and 3N, a second electrical interconnection line 50 may be arranged at the second electrode 46. In another embodiment, the second electrical interconnection line 50 may be directly arranged at and/or contacted to the resistive storage region 44. In one aspect the second electrical interconnection line 50 may have a longitudinal extent substantially perpendicular to a longitudinal extent of the first electrical interconnection line 38.

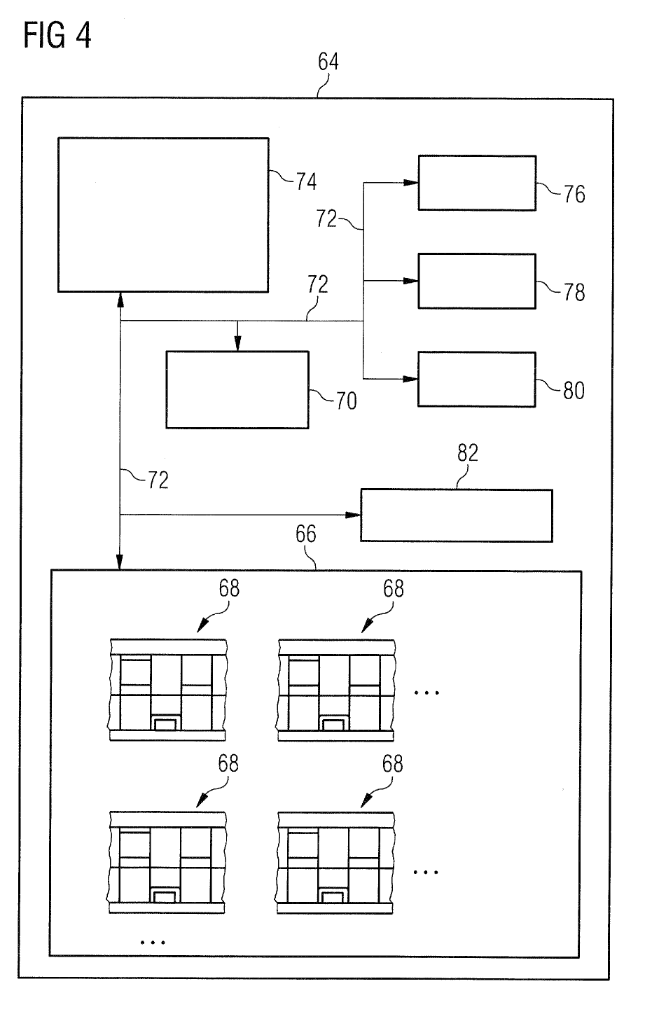

In yet another embodiment shown in FIG. 4, a system 64 or electronic device such as a computer (e.g. a mobile computer), a mobile phone, a pocket PC, a smart phone, a PDA, for example, or any kind of consumer electronic device, such as a TV, a radio, or any house hold electronic device, for example, or any kind of storage device, such as a chip card or memory card, for example, comprises one or more storage components or memories 66. The memory 66 may comprise one or more a storage cells 68 which may be configured according to one or more of the above described integrated circuits 10, for example. In one embodiment, the memory 66 may comprise a substrate, such as the substrate 12 described above, for example, having a substrate normal direction 14. The memory 66 may further comprise a first structured electrical connection layer, such one of the above described first structured electrical connection layers 34, for example, which comprises a first electrode, such as one of the above described first electrodes 36, for example, and a first electrical interconnection line, such as one of the above described electrical interconnection lines 38, for example. The memory 66 may further comprise a resistive storage region, such as one of the above described resistive storage regions 36, for example, arranged, in substrate normal direction 14, on top of the first electrode. The memory 66 may further comprise an interconnection structure mask, such as one of the above described interconnection structure masks 48, for example, arranged, in substrate normal direction, on top of the first electrical interconnection line.

In one embodiment, the first structured electrical connection layer may comprise a plurality of first electrodes that are arranged in an array comprising rows and columns. According to one particular example, the memory 66 may comprise a plurality of resistive storage regions each being arranged, in substrate normal direction, on top of one of the plurality of first electrodes, and a plurality of second electrical interconnection lines that are at least partly separated from the first electrical interconnection line through the interconnection structure mask. The resistive storage regions within each column may be electrically connected to a common second electrical interconnection line.

In one embodiment, the system 64 may comprise a processing unit 70 and a system bus 72 that couples various system components including the storage component 66 (or memory) to the processing unit 70. The processing unit 70 may perform arithmetic, logic and/or control operations by accessing the storage component 66, for example. The storage component 66 may store information and/or instructions for use in combination with the processing unit 70. The storage component 66 may comprise volatile and/or non-volatile memory cells. The storage component 66 may be implemented as a random access memory (RAM), for example. In one example, a basic input/output system (BIOS) storing the basic routines that helps to transfer information between elements within the electronic device or system 64, such as during start-up, may be stored in the storage component 66. The system bus 72 may be any of several types of bus structures including a memory bus or memory controller, a peripheral bus, and a local bus using any of a variety of bus architectures.

In one embodiment, the system 64 may further comprise an input apparatus and an output apparatus. In particular, the electronic device or system 64 may comprise a video input and/or output device 74, such as a display interface and/or a display device and/or a camera, connected to the system bus 72, for example. Alternatively or in addition to the video device 74 the system 64 may comprise an audio device 76 for inputting and/or outputting acoustic signals, such as a speaker and/or a microphone, for example. Moreover, in one example, the system 64 may comprise an input interface 78, such as input keys and/or an interface for connecting a keyboard, a joystick and/or a mouse, for example. In yet another embodiment, the electronic device 64 may comprise a network interface 80 for connecting the electronic device to a wired and/or a wireless network. Furthermore, one or more additional memory components 82 may be comprised in the electronic device or system 64.

In one embodiment, the storage component or memory 66 is implemented as a data memory for storing computer readable instructions, data structures, program modules and/or other data for the operation of the system 64. In another embodiment, the storage component 66 may be implemented as a graphical memory or an input/output buffer. In one embodiment the storage component 48 is fixedly connected to the system 64. In another embodiment, the storage component 66 is implemented as a removable component, such as a memory card or chip card, for example.

A number of examples and implementations have been described. Other examples and implementations may, in particular, comprise one or more of the above features. In one example an integrated circuit or a memory device as described above may be fabricated by one or more of the methods described herein. Nevertheless, it will be understood that various modifications may be made. In particular, features, properties, and modifications of single elements, components or processes described in connection with one particular example can be analogously applied to the corresponding elements, components and processes of the other described examples. Furthermore, although in all of the examples shown in the figures the first electrode and/or the first electrical interconnection lines are directly fabricated on a process surface of a select circuitry, neither the integrated circuit, nor the method of fabricating an integrated circuit is limited to this. In particular, instead of the surface of a pre-metal dielectric layer, any process surface may be provided for the carrying out subsequent fabrication steps. Accordingly, other implementations are within the scope of the following claims.

What is claimed is:

1. A method of fabricating an integrated circuit, the method comprising:
providing an electrode structure stack comprising a first electrode and an electrode structure mask arranged at the first electrode;
forming a support structure at least partly at the electrode structure mask;
removing the electrode structure mask to leave a storage region window in the support structure; and
forming a resistive storage region in the storage region window at the first electrode.

2. The method of claim 1, wherein providing an electrode structure stack comprises:
forming the electrode structure mask at a first electrical connection layer; and
etching at least part of the first electrical connection layer, while applying the electrode structure mask as an etch mask.

3. The method of claim 2, wherein forming the electrode structure mask at the first electrical connection layer comprises:
forming a structure mask layer at the first electrical connection layer; and
lithographically structuring the structure mask layer to form the electrode structure mask.

4. The method of claim 1, wherein forming the support structure comprises:
depositing a support material layer; and
planarizing the support material layer to at least partly uncover the electrode structure mask.

5. The method of claim 1, wherein removing the electrode structure mask comprises selectively etching the electrode structure mask at the support structure and the first electrode.

6. The method of claim 1, wherein forming a resistive storage region comprises:
depositing a storage medium layer; and
planarizing the storage medium layer to at least partly uncover the support material layer.

7. The method of claim 1, further comprising forming a second electrode at the resistive storage region.

8. A method of fabricating an integrated circuit, comprising:
forming an interconnection structure mask at a first electrical connection layer;
etching at least part of the first electrical connection layer with the interconnection structure mask being applied as an etch mask to form at least one first electrical interconnection line;
depositing a dielectric layer;
planarizing the dielectric layer to at least partly uncover the interconnection structure mask; and
forming at least one second electrical interconnection line at least partly at the uncovered interconnection structure mask.

9. The method of claim 8, wherein forming the interconnection structure mask at the first electrical connection layer comprises:
forming a structure mask layer at the first electrical connection layer; and
lithographically structuring the structure mask layer to form the interconnection structure mask.

10. A method of fabricating an integrated circuit, the method comprising:
forming a structure mask at a first electrical connection layer, the structure mask comprising an electrode structure mask and an interconnection structure mask;
etching at least part of the first electrical connection layer with the structure mask being applied as an etch mask to form at least one first electrode and at least one first electrical interconnection line;
depositing a dielectric filling material;
planarizing the dielectric filling material to at least partly uncover the electrode structure mask;
removing the electrode structure mask to uncover at least part of the first electrode, while maintaining the interconnection structure mask; and
forming a resistive storage region at the first electrode.

11. The method of claim 10, wherein forming the structure mask at the first electrical connection layer comprises:
forming a structure mask layer at the first electrical connection layer; and
lithographically structuring the structure mask layer to form the electrode structure mask and the interconnection structure mask.

12. The method of claim 10, wherein planarizing the dielectric filling material comprises at least partly uncovering the interconnection structure mask, and wherein the method further comprises providing a protection mask to cover the uncovered interconnection structure mask.

13. The method of claim 10, further comprising forming a second electrode at the resistive storage region.

14. The method of claim 13, further comprising forming a second electrical interconnection line at the second electrode

15. The method of claim 10, further comprising:
electrically connecting the first electrode with a first source/drain contact of a select transistor; and
electrically connection the first interconnection line with a second source/drain contact of the select transistor.

16. The method of claim 10, wherein the resistive storage region comprises a solid state electrolyte.

17. An integrated circuit, comprising:
a substrate having a substrate normal direction;
a first structured electrical connection layer, comprising:
a first electrode; and
a first electrical interconnection line;
a resistive storage region arranged, in the substrate normal direction, on top of the first electrode; and
an interconnection structure mask arranged, in the substrate normal direction, on top of the first electrical interconnection line.

18. The integrated circuit of claim 17, comprising a dielectric filling structure that is at least partly arranged between the first electrode and the first electrical interconnection line and that forms together with the interconnection structure mask at least part of a substantially planar interconnection interface.

19. The integrated circuit of claim 18, comprising a second structured electrical connection layer arranged at the interconnection interface, wherein the second structured electrical connection layer comprises at least one second electrical interconnection line that is electrically connected to the resistive storage region.

20. The integrated circuit of claim 17, comprising a select transistor that has a first source/drain region and a second source/drain region, wherein the first electrode is electrically connected to the first source/drain region and the first electrical interconnection line is electrically contacted to the second source/drain region of the select transistor.

21. The integrated circuit of claim 17, wherein the width of the first electrode and the resistive storage region in directions perpendicular to the substrate normal direction is between about 30 nm and about 100 nm.

22. A resistive storage device, comprising:
a substrate having a substrate normal direction;
a first structured electrical connection layer, comprising:
a plurality of first electrodes that are arranged in an array comprising rows and columns; and
a first electrical interconnection line;
a plurality of resistive storage regions each being arranged, in the substrate normal direction, on top of one of the plurality of first electrodes;
an interconnection structure mask arranged, in the substrate normal direction, on top of the first electrical interconnection line; and
a plurality of second electrical interconnection lines that are at least partly separated from the first electrical interconnection line through the interconnection structure mask, wherein the resistive storage regions within each column are electrically connected to a common second electrical interconnection line.

23. A system comprising an input apparatus, an output apparatus, a processing apparatus and a memory, said memory comprising:
a substrate having a substrate normal direction;
a first structured electrical connection layer, comprising:
a first electrode; and
a first electrical interconnection line;
a resistive storage region arranged, in the substrate normal direction, on top of the first electrode; and
an interconnection structure mask arranged, in the substrate normal direction, on top of the first electrical interconnection line.

24. The system of claim 23, wherein the first structured electrical connection layer comprises a plurality of first electrodes that are arranged in an array comprising rows and columns, and wherein the memory comprises:
a plurality of resistive storage regions each being arranged, in the substrate normal direction, on top of one of the plurality of first electrodes; and
a plurality of second electrical interconnection lines that are at least partly separated from the first electrical interconnection line through the interconnection structure mask, wherein the resistive storage regions within each column are electrically connected to a common second electrical interconnection line.
